(19) United States
(12) Patent Application Publication
(10) Pub. No.: US 2025/0096072 A1
(43) Pub. Date: Mar. 20, 2025

(54) THERMAL MANAGEMENT SYSTEM FOR MULTIPLE DIES

(71) Applicant: Microsoft Technology Licensing, LLC

(72) Inventors: Bharath RAMAKRISHNAN, Bellevue, WA (US); Vaidehi ORUGANTI, Kirkland, WA (US); Husam Atallah ALISSA, Redmond, WA (US)

(21) Appl. No.: 18/368,936

(22) Filed: Sep. 15, 2023

(51) Int. Cl. H01L 23/473; H01L 21/268; H01L 25/065

(52) U.S. Cl. CPC H01L 23/473; H01L 21/268; H01L 25/0655

(57) ABSTRACT

The present disclosure relates to thermal management systems in an electronic device. In particular, the systems described herein provide a microfluidic channel between a first die and a second die that acts as an insulating layer between the first die and the second die to prevent heat transfer between the two dies. The systems described herein further provide a first inlet for the first die configured to receive a first working fluid at a first temperature, and a second inlet for the second die configured to receive a second working fluid at a second temperature, therefore providing heterogenous cooling for each die in an integrated chip package.

### CROSS-REFERENCE TO RELATED APPLICATIONS

N/A

### BACKGROUND

Thermal management of integrated chips of high-performance computing devices removes relatively large quantities of heat from a small area of volume. Conventional thermal management systems connect a working fluid to the integrated chips through a metallic heat sink or other interface. Providing heterogeneous cooling for each die in the integrated chip package separately can improve thermal management performance.

### BRIEF SUMMARY

In some embodiments, a thermal management system for electronic device is provided. The system includes a circuit board, a first die and a second die in an integrated chip, where the first die and the second die are laterally adjacent to each other and connected to the circuit board. The system further includes a microfluidic channel between the first die and the second die, where the microfluidics channel acts as an insulating layer.

In other embodiments, a thermal management system for electronic device is provided. The system includes a circuit board, a first die and a second die, where the first die and the second die are laterally adjacent to each other and connected to the circuit board. The system further includes a side-channel between the first die and the second die where the side-channel acts as an insulating layer. The system further includes one or more thermal elements on top of the first die and the second die.

In yet other embodiments, a thermal management system for electronic device is provided. The system includes a circuit board, a first die and a second die, wherein the first die and the second die are laterally adjacent to each other and connected to the circuit board. The system further includes a first inlet for the first die configured to receive a first working fluid at a first temperature, and a second inlet for the second die configured to receive a second working fluid at a second temperature, and wherein the first temperature and the second temperature are different.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims, or may be learned by the practice of such embodiments as set forth hereinafter.

### BRIEF DESCRIPTION OF THE DRAWINGS

In order to describe the manner in which the above-recited and other features of the disclosure can be obtained, a more particular description will be rendered by reference to specific implementations thereof, which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIGS. 1A and 1B illustrate a thermal management system between two dies that are laterally adjacent to each other and connected to a circuit board, in accordance with one or more embodiments.

FIG. 2 illustrates a cross sectional sideview of a thermal management system between two dies that are laterally adjacent to each other and connected to a circuit board, in accordance with one or more embodiments.

FIGS. 3A and 3B illustrate a thermal management system for an electronic device having two dies, a side-channel between the two dies and one or more thermal elements on top of the two dies, in accordance with one or more embodiments.

FIGS. 4A and 4B illustrate a thermal management system for an electronic device having two dies, a side-channel between the two dies and one or more thermal elements on top of the two dies, in accordance with one or more embodiments.

FIG. 5A illustrates a cross-sectional sideview of two dies that are laterally adjacent to each other and connected to a circuit board, and a side-channel between the two dies, wherein the side-channel acts as an insulating layer, in accordance with one or more embodiments.

FIG. 5B illustrates a cross-sectional top-down view of one or more thermal elements located on top of a first die and a second die, in accordance with one or more embodiments.

FIG. 6A illustrates a cross-sectional sideview of two dies that are laterally adjacent to each other and configured to receive separate working fluids, in accordance with one or more embodiments.

FIG. 6B illustrates a cross-sectional top-down view of one or more thermal elements located on top of a first die and a second die, in accordance with one or more embodiments.

FIG. 7A illustrates a thermal management system for an electronic device having two separate fluid reservoirs, in accordance with at least one or more embodiments.

FIG. 7B illustrates a thermal management system for an electronic device having a single fluid reservoir for two or more inlets and two or more outlets, in accordance with at least one or more embodiments.

FIG. 8 illustrates a series of acts for preventing heat transfer between a first die and a second die, in accordance with at least one or more embodiments.

### DETAILED DESCRIPTION

This disclosure generally relates to heat management system on an integrated chip including two or more laterally adjacent dies. Integrated chips include a combination of multiple dies, where each die is attached to a common printed circuit board (PCB). Generally, a die is a small block of semiconducting material on which a given functional circuit is fabricated. Different dies may have different functionalities, such as memory, processor, etc. Each different die having a different functionality, may produce different amount of heat based on the amount of power consumed and/or the size of the die. When dies are close together part of the heat generated by a more powerful die may transfer to an adjacent die. In some cases, the heat transfer between two dies may be up to 40% of all heat generated by a single die. This type of heat transfer between dies is undesired.

Traditionally, cooling is provided to an integrated chip as a whole. Each die in the integrated chip package traditionally includes a first thermal interface on top of the die, a heat spreader package on top of the first thermal interface, and a second thermal interface on top of the heat spreader package. In addition, when two dies have different vertical height from the circuit board, the lower die is typically brought to the same vertical height with the higher die by adding another layer of thermal (or other) material (such as silicon) on top of the lower die. When all the dies are at the same level, a heat sink may be installed on top of the entire package to cool the entire package down.

The features and functionalities described herein provide a number of advantages and benefits over conventional approaches and systems. For example, the systems described herein provide features and functionalities relating to cooling integrated chips. Indeed, the systems described herein provide a system for preventing heat transfer between two adjacent dies by providing a microfluidics channel between the two dies.

In addition to limiting and/or preventing heat transfer between two adjacent dies, one or more embodiments of the systems described herein include features relating to providing separate cooling for adjacent dies in an integrated chip. For example, two different temperature working fluids can be provided to two adjacent dies. One possible advantage of providing different temperature working fluids to different dies is that higher performing dies that produce more heat can be cooled more efficiently than if generic cooling is provided for all dies together. For example, efficiency may be improved by providing 20 C cooling to a first die and a 40 C cooling to a second die.

In addition to providing separate cooling for adjacent dies, one or more embodiments of the systems described herein allow cooling directly on the die by removing thermal material and heat spreaders between a die and a heat sink or by producing a heat sink directly on a die. For example, a cooling may be provided directly on the surface of the die (e.g., on the silicon) without the need to include additional thermal layers on top of the die. By cutting down the thermal resistance stack, a higher temperature working fluid may be used for cooling, than with the traditional methods.

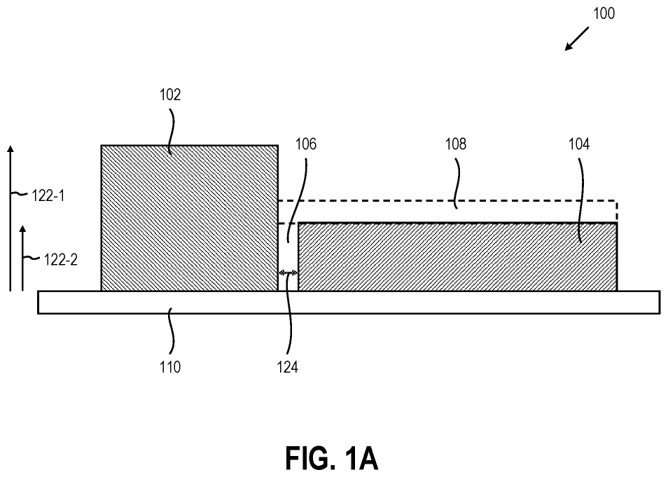

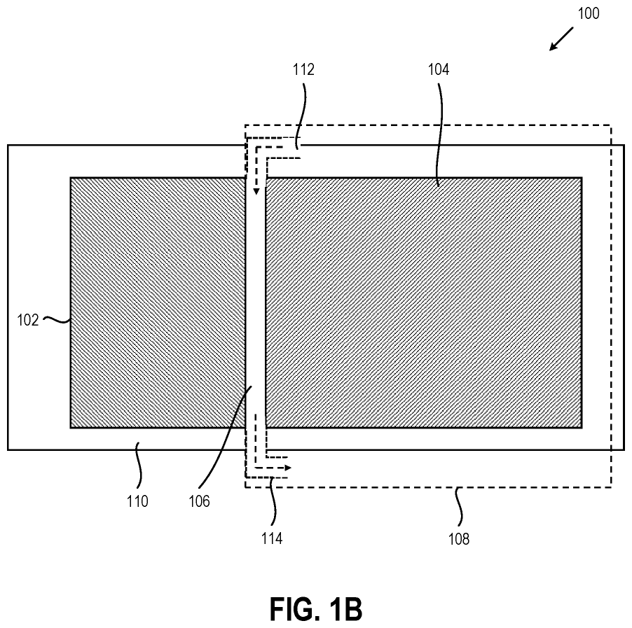

FIGS. 1A and 1B illustrate a thermal management system 100 between two dies that are laterally adjacent to each other and connected to a circuit board 110, in accordance with one or more embodiments. FIG. 1A shows a cross-sectional sideview and FIG. 1B shows a cross-sectional top-down view of a first die 102 and a second die 104 that are connected to a circuit board 110. In one or more embodiments, the circuit board 110 is a printed circuit board (PCB). In one or more embodiments, the first die 102 and the second die 104 may be different. For example, the first die 102 may be a high bandwidth memory (HBM) and the second die 104 may be a central processing unit (CPU). In another example, the first die 102 may be a graphics processing unit (GPU) and the second die 104 may be a field-programmable gate array (FPGA). In one or more embodiments, the first die 102 and/or the second die 104 may be an integrated circuit holding many different components. For example, the first die 102 may be a photonic integrated circuit (PIC) and the second die 104 may be a system on a chip (SoC). In one or more embodiments, one or more of the first die 102 and/or the second die 104 may be one or more of a logical chip, a memory chip, an application-specific chip (ASICs) and a system-on-a-chip (SoC). In one or more embodiments, the first die 102 and the second die 104 are configured to operate below a first junction temperature and below a second junction temperature respectively. For example, the first die 102 may be configured to operate under 40 degrees of Celsius (C), while the second die 104 may be configured to operate under 20 degrees of Celsius. In one or more embodiments, the first junction temperature and the second junction temperature may be the same temperature.

As shown in FIGS. 1A and 1B, the first die 102 and the second die 104 are laterally adjacent to each other on the circuit board 110. A microfluidic channel 106 is positioned between the first die 102 and the second die 104 wherein the microfluidic channel 106 acts as an insulating layer. For example, when the first die 102 generates a heat flux of 50 W per cm² and the second die 104 generates a heat flux of 800 W per cm², the higher heat generated by the second die 104 will not transfer over to the lower heat generating die, the first die 102, as the microfluidic channel 106 acts as an insulating layer between the first die 102 and the second die 104. In one or more embodiments, the microfluidic channel width 124 is between 10 to 25 micrometers. In one or more embodiments, the system includes more than one microfluidic channel 106 between the first die 102 and the second die 104. For example, there may be two adjacent channels between the first die 102 and the second die 104. In another example, there may be three or more adjacent channels between the first die 102 and the second die 104. In one or more embodiments, the microfluidic channel 106 is configured to transport working fluids. In one or more embodiments, the working fluid is a liquid working fluid. For example, a deionized water, a glycol-water solution, a dielectric fluid, such as fluorocarbons, other working fluids, or combinations thereof. In one or more embodiments, the working fluid is a gaseous working fluid (e.g., helium and carbon dioxide). In one or more embodiments, the working fluid is substantially single-phase working fluid. For example, a single-phase working fluid remains in a single physical phase (e.g., a liquid) throughout the operation of the thermal management system 100. In one or more embodiments, the working fluid is a two-phase working fluid. For example, a two-way working fluid transitions between physical phases (e.g., liquid to gas; gas to liquid) as heat is received or exhaust from the working fluid during operation of the thermal management system 100.

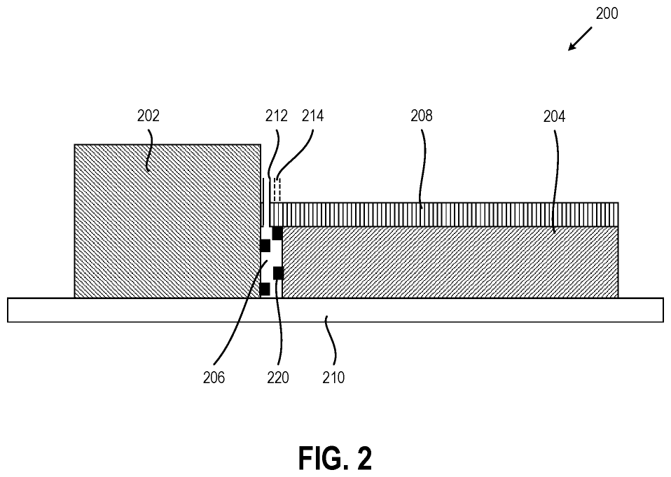

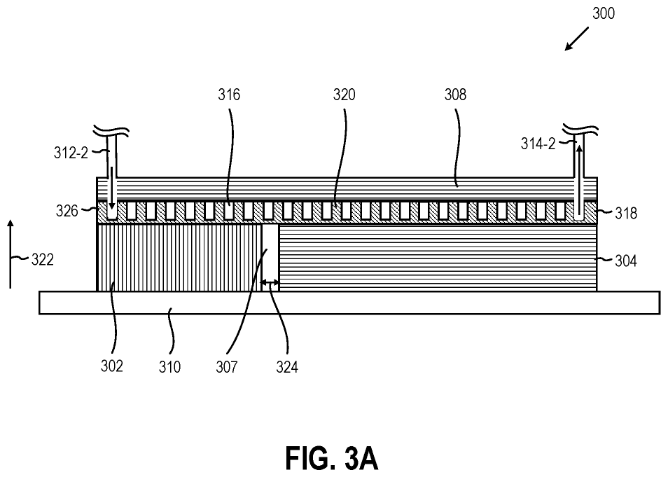

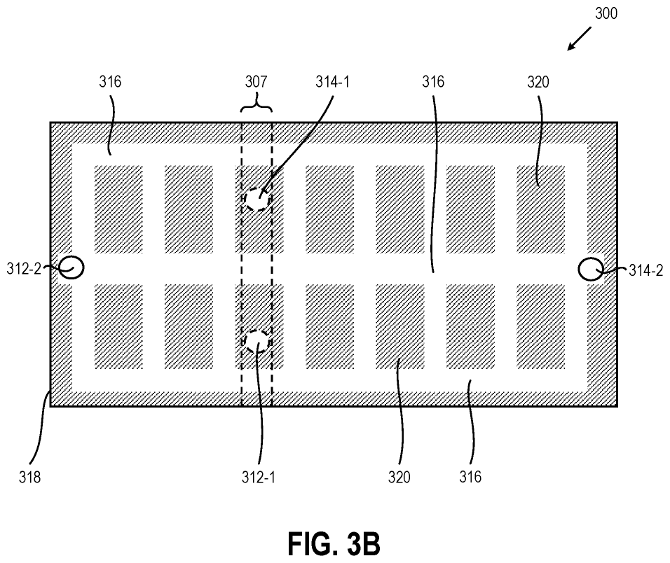

In one or more embodiments, the microfluidics channel is capped with a manifold 108. For example, the manifold 108 may provide a closed volume for the microfluidics channel 106 and wherein the manifold 108 may provide an inlet 212 and an outlet 214 for a working fluid to flow to and from a microfluidic channel 206, as further discussed in connection with FIG. 2. In one or more embodiments, the inlet 112 and/or the outlet 114 is provided through the side of the manifold 108 as optionally shown on FIG. 1B. In one or more embodiments, an inlet 212 and an outlet 214 are provided through a top of a manifold 208, as further discussed in connection with FIG. 2. In one or more embodiments, multiple inlets 312-1, 312-2 and/or multiple outlets 314-1, 314-2 are provided, as described, for example, in connection with FIG. 3B.

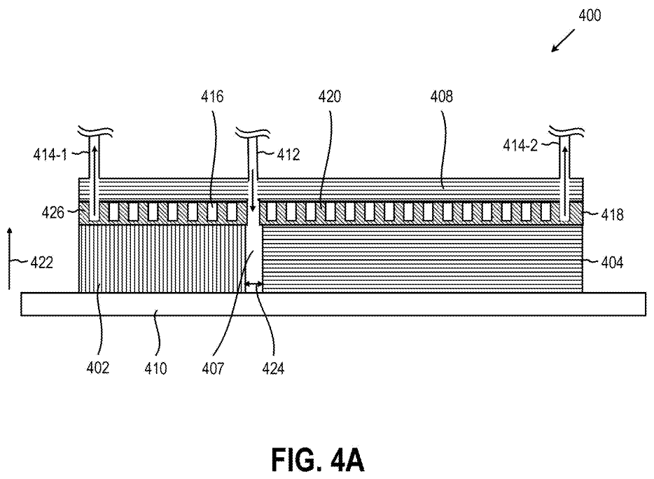

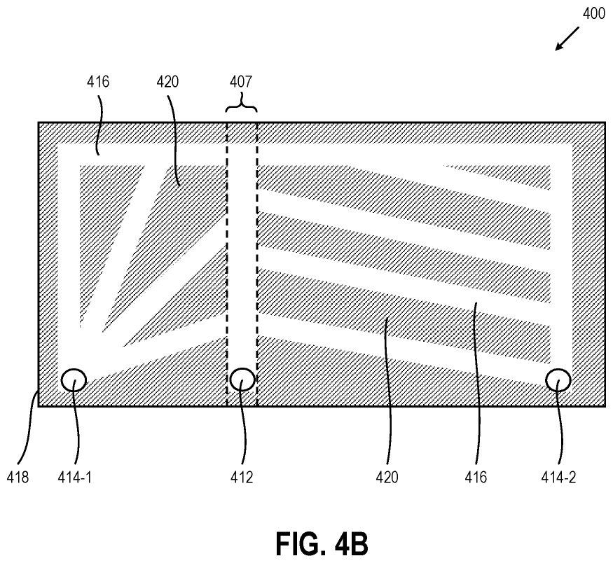

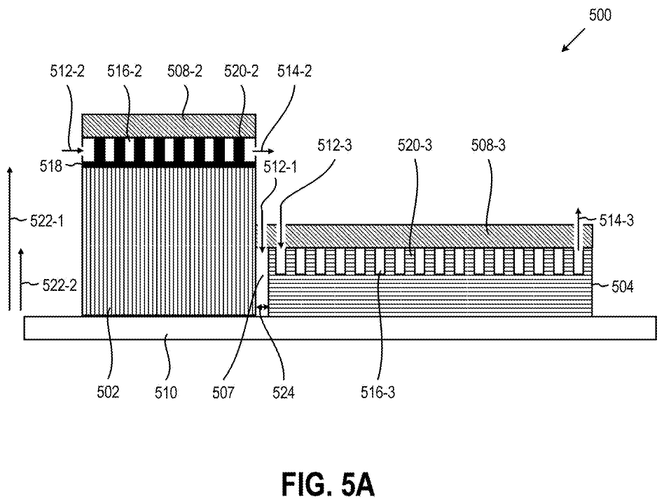

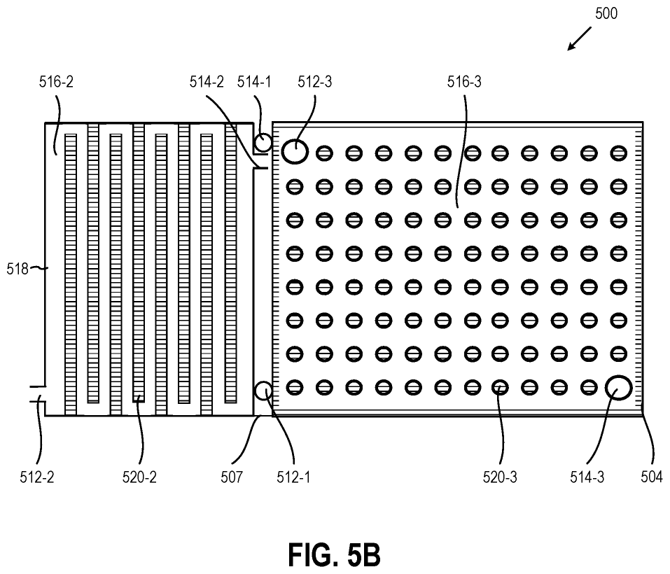

It should be noted that even though the first die 102 and the second die 104 are pictured in FIG. 1A as having different vertical heights 122-1, 122-2 (e.g., thickness) (also shown in FIG. 5A as 522-1, 522-2), in one or more embodiments, dies are the same vertical height 322, 422, in which case a manifold 308, 408 may cover both a first die 302, 402 and a second die 304, 404 as further shown in FIGS. 3A and 4A. In one or more embodiments, a manifold only covers a microfluidic channel and not a first die nor the second die.

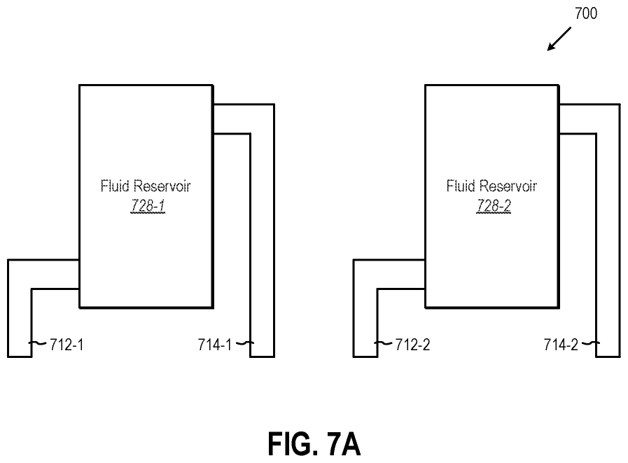

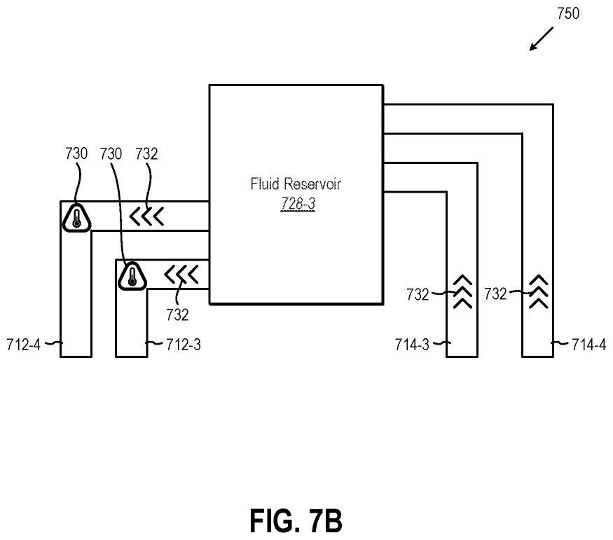

In one or more embodiments, the system includes a pump that delivers the working fluid to the microfluidic channel 106, as further discussed in connection with FIGS. 7A and 7B. For example, the pump may provide pressurized water to the microfluidic channel 106 through the inlet 112.

FIG. 2 illustrates a cross-sectional sideview of a thermal management system 200 between two dies that are laterally adjacent to each other and connected to a circuit board 110, in accordance with one or more embodiments. As shown in FIG. 2 a first die 202 and a second die 204 are connected to a circuit board 210 and a microfluidic channel 206 is positioned between the first die 202 and the second die 204. In one or more embodiments, the first die 202 and the second die 204 have any or all of the features and functionalities as the first die 102 and the second die 104 as described in connection with FIGS. 1A and 1B. Similarly, the microfluidic channel 206 and the manifold 208 include, in one or more embodiments, the functionalities and features of the microfluidic channel 106 and the manifold 108 described in connection with FIGS. 1A and 1B.

As shown in FIG. 2, the microfluidic channel 206 may include one or more thermal elements 220 on a surface of one or more of the first die 202 and the second die 204. In one or more embodiments, the thermal elements 220 define one or more channels in the outer surface of the first die 202, the second die 204, or a combinations thereof. In one or more embodiments, the thermal element 220 includes a pin, a fin (e.g., a long straight section similar to a standard heat sink fin), a pin-fin (e.g., cylindrical structure), or combinations thereof. In one or more embodiments, the one or more thermal elements 220 are formed by removing die material from the outer surface of the one of more of the first die 202 and the second die 204. For example, the die material may be removed by laser etching and/or ablation. In another example, the die material may be removed by chemical etching, lithography, skiving, or combinations thereof. In one or more embodiments, the one or more thermal elements 220 are formed by additive manufacturing process to the surface of one or more of the first die 202 and the second die 204. For example, the additive manufacturing process may add the same material to the outer surface of the die as that of the outer surface of the die component (e.g., silicon). In another example, the additive manufacturing process may add thermal material to the outer surface of the die that is different material as that of the outer surface of the die component. In one or more embodiments, the material is added by a focused ion beam to deposit material. In one or more embodiments, material is added by selective laser melting or selective laser sintering. In one or more embodiments, material is added by lamination of material. In one or more embodiments, material is added by polymerization, such as photo-polymerization. In one or more embodiments, material is added by ion sputtering. In one or more embodiments, material is extruded onto the outer surface of the first die and/or the second die or another surface covering the die material. In one or more embodiments, one or more portions of the thermal elements are attached to a die. For example, the thermal elements may be preformed and glued to one or more dies.

As shown in FIG. 2 the thermal management system 200 may further include a manifold 208. For example, the manifold 208 may provide a closed volume for the microfluidics channel 206 and wherein the manifold 208 may provide an inlet 212 and an outlet 214 for a working fluid to flow to and from a microfluidic channel 206. In one or more embodiments, an inlet 112 and/or the outlet 114 are provided through the side of the manifold 108 as previously shown on FIG. 1B. In one or more embodiments, the inlet 212 and the outlet 214 are provided through the top of the manifold 208, as shown in FIG. 2.

FIGS. 3A and 3B illustrate a thermal management system 300 for an electronic device having two dies (302, 304), a side-channel 307 between the two dies, and one or more thermal elements 320 on top of the two dies, in accordance with one or more embodiments. FIG. 3A shows a cross-sectional sideview of a first die 302 and a second die 304 that are laterally adjacent to each other and connected to a circuit board 310, and a side-channel 307 between the first die 302 and the second die 304, wherein the side-channel 307 acts as an insulating layer. FIG. 3B shows a cross-sectional top-down view of one or more thermal elements 320 located on top of the first die 302 and the second die 304.

In one or more embodiments, the circuit board 310 is a printed circuit board (PCB). In one or more embodiments, the first die 302 and the second die 304 have any or all of the features and functionalities of the first die 102 and the second die 104 as described in connection with FIGS. 1A and 1B. In one or more embodiments, the side-channel 307 is a microfluidic channel, such as the microfluidic channels 106, 206 discussed in connection with FIGS. 1A-1B and FIG. 2. In one or more embodiments, the side-channel 307 is an air channel. In one or more embodiments, the side-channel width 324 is between 10 to 25 micrometers. In one or more embodiments, the system includes more than one side-channel 307 between the first die 302 and the second die 304. For example, there may be two adjacent channels between the first die 302 and the second die 304.

In the embodiment shown in FIG. 3A, the one or more thermal elements 320 are placed on an additional thermal layer 318 that is positioned on top of the first die 302, the second die 304, and the side-channel 307. For example, the additional thermal layer 318 may be silicon. In one or more embodiments, additional thermal layer 318 includes the one or more thermal elements 320 at the outer top surface 326, such as pins, fins, pin-fins, or a combination thereof. These one or more thermal elements 320 may define one or more channels 316 in the outer top surface 326 of the additional thermal layer 318. For example, the one or more channels 316 may be microfluidic channels. FIG. 3B shows a top-down view of the additional thermal layer 318 with one possible formation including one or more thermal elements 320 and one or more channels 316. As shown in FIGS. 3A and 3B, an inlet 312-2 is provided to the channel 316, and an outlet 314-2 is provided from the channel 316.

As shown in FIGS. 3A and 3B, a side-channel 307 may be provided between the first die 302 and the second die 304, wherein the side-channel 307 is not connected with the one or more channels 316. In one or more embodiments, an inlet 312-1 and an outlet 314-1 to and from the side-channel 307 are provided through the additional thermal layer 318, as shown in FIG. 3B. In this way, the working fluid may configured to flow into and/or through the one or more channels 316 of the additional thermal layer 318 and does not interfere with the side-channel 307 cooling system. In one or more embodiments, the one or more channels 416 and the side-channel 407 are connected with each other, as further discussed in connection with FIGS. 4A and 4B.

In one or more embodiments, the one or more channels 316 and the side-channel 307 may be configured to receive working fluids in different physical phases. For example, the one or more channels 316 may be configured to receive a liquid working fluid, while the side-channel 307 may be configured to receive gaseous working fluid. In one or more embodiments, the one or more channels 316 and the side-channel 307 are configured to receive fluids at different temperature. For example, the one or more channels 316 may be configured to receive a working fluid at 20 degrees Celsius, while the side-channel 307 may be configured to receive a working fluid at 40 degrees Celsius. In one or more embodiments, the one or more channels 316 and the side-channel 307 are configured to receive working fluids at the same physical phases and/or at the same temperature.

In one or more embodiments, the one or more thermal elements 320 are formed by removing the additional thermal layer 318 material from the outer top surface 326 of the additional thermal layer 318. In one or more embodiments, the one or more thermal elements 320 are formed by additive manufacturing process to the outer top surface 326 of the additional thermal layer 318. In one or more embodiments, the one or more thermal elements 520-3 are formed by removing die material from the outer surface of the first die and the second die, as further discussed in connection with FIGS. 5A and 5B. In one or more embodiments, the one or more thermal elements 320 are formed by additive manufacturing process to the outer top surface of the first die 302 and the second die 304.

As shown in FIG. 3A, the additional thermal layer 318 including the one or more thermal elements 320 and the one or more channels 316 is capped with a manifold 308. For example, the manifold 308 may provide a closed volume for any working fluid to travel and wherein the manifold 308 further provides the inlet 312-2 and the outlet 314-2 to the one or more channels 316 and the inlet 312-1 and the outlet 314-1 to the side-channel 307. As shown in FIGS. 3A and 3B the inlets 312-1, 312-2 and the outlets 314-1, 314-2 are provided through the top of the manifold 308. In one or more embodiments, one or more of the inlet 512-2, and the outlet 514-2 are provided through the side of the manifold, as further discussed in connection with FIGS. 5A and 5B. As shown in FIG. 3B, the inlet 312-1 and the outlet 314-1 are provided through the manifold 308 and through the additional thermal layer 318. In one or more embodiments, the inlet 312-1 and the outlet 314-1 are provided through the side of the manifold 308.

In one or more embodiments, there are multiple inlets and/or multiple outlets in the thermal management system. In one or more embodiments, the system further includes one or more pumps that delivers a working fluid to the one or more channels 316 and the side-channel 307, as further discussed in connection with FIGS. 7A and 7B. For example, the one or more pumps may provide pressurized working fluid to the one or more channels 316 through the inlet 312-2 and to the side-channel 307 through the inlet 312-1. In one or more embodiments, the system further includes one or more fans that deliver gaseous working fluid to the one or more channels 316 and the side-channel 307.

FIGS. 4A and 4B illustrate a thermal management system 400 for an electronic device having two dies (402, 404), a side-channel 407 between the two dies, and one or more thermal elements 420 on top of the two dies, in accordance with one or more embodiments. FIG. 4A shows a cross-sectional sideview of a first die 402 and a second die 404 that are laterally adjacent to each other and connected to a circuit board 410, and a side-channel 407 between the first die 402 and the second die 404, wherein the side-channel 407 acts as an insulating layer. FIG. 4B shows a cross-sectional top-down view of the one or more thermal elements 420 on top of the first die 402, the second die 404, and the side-channel 407.

In one or more embodiments, the circuit board 410 is a printed circuit board (PCB). In one or more embodiments, the first die 402 and the second die 404 have any or all of the features and functionalities of the first die 102 and the second die 104 as described in connection with FIGS. 1A and 1B. In one or more embodiments, the side-channel 407 is a microfluidic channel, such as the microfluidic channel 106 discussed in connection with FIGS. 1A and 1B. In one or more embodiments, the side-channel 407 is an air channel. In one or more embodiments, the side-channel width 424 is between 10 to 25 micrometers. In one or more embodiments, the system includes more than one side-channel 407 between the first die 402 and the second die 404. For example, there may be two adjacent channels between the first die 402 and the second die 404.

In the embodiment shown in FIG. 4A, the one or more thermal elements 420 are placed on an additional thermal layer 418 that is positioned on top of the first die 402, the second die 404, and the side-channel 407. For example, the additional thermal layer 418 may be silicon. In one or more embodiments, the additional thermal layer 418 includes the one or more thermal elements 420 at the outer top surface 426, such as pins, fins, pin-fins, or a combination thereof. These one or more thermal elements 420 may define one or more channels 416 in the outer top surface 426 of the additional thermal layer 418.

FIG. 4B shows a top-down view of the additional thermal layer 418 with one possible formation including one or more thermal elements 420 and one or more channels 416. As shown in FIGS. 4A and 4B, the one or more channels 416 and the side-channel 407 are connected to each other. A single inlet 412 is provided to the thermal systems, and two outlets 414-1 and 414-2 are provided. In one or more embodiments, the one or more channels 416 and the side-channel 407 are microfluidic channels. In one or more embodiments, the inlet 412 is configured to provide a working fluid to the one or more channels 416 and the side-channel 407.

In one or more embodiments, the one or more thermal elements 420 formed by removing additional thermal layer 418 material from the outer top surface 426 of the additional thermal layer 418. In one or more embodiments, the one or more thermal elements 420 are formed by additive manufacturing process to the outer top surface 426 of the additional thermal layer 418. In one or more embodiments, the one or more thermal elements 520-3 are formed by removing die material from the outer surface of the first die and the second die, as further discussed in connection with FIGS. 5A and 5B. In one or more embodiments, the one or more thermal elements 420 are formed by additive manufacturing process to the outer top surface of the first die 402 and the second die 404.

As shown in FIG. 4A, the additional thermal layer 418, including the one or more thermal elements 420 and the one or more channels 416, is capped with a manifold 408. For example, the manifold 408 may provide a closed volume for any working fluid to travel and wherein the manifold 408 further provides the inlet 412 and the outlets 414-1 and 414-2 to the one or more channels 416 and the side-channel 407. As shown in FIGS. 4A and 4B, the inlet 412 and the outlets 414-1 and 414-2 are provided through the top of the manifold 408. In one or more embodiments, the inlet and the outlet are provided through the side of the manifold, as further discussed in connection with FIGS. 5A and 5B. It should be noted that even if the example here shows one inlet 412 and two outlets 414-1 and 414-2, the thermal system includes, in one or more embodiments, any number of inlets and outlets.

In one or more embodiments, the system further includes one or more pumps that delivers the working fluid to the one or more channels 416 and the side-channel 407. For example, the one or more pumps may provide pressurized working fluid to the one or more channels 416 through the inlet 412 and to the side-channel 407. In one or more embodiments, the system further includes one or more fans that deliver gaseous working fluid to the one or more channels 416 and the side-channel 407.

FIGS. 5A and 5B illustrate a thermal management system 500 for an electronic device having two dies that have different vertical heights (502, 504), a side-channel 507 between the two dies and one or more thermal elements (520-2, 520-3) on top of the two dies, in accordance with one or more embodiments. FIG. 5A shows a cross-sectional sideview of a first die 502 and a second die 504 that are laterally adjacent to each other and connected to a circuit board 510, and a side-channel 507 between the first die 502 and the second die 504, wherein the side-channel 507 acts as an insulating layer. FIG. 5B shows a cross-sectional top-down view of one or more thermal elements (520-2 and 520-3) located on top of the first die 502 and the second die 504 respectively.

In one or more embodiments, the circuit board 510 is a printed circuit board (PCB). In one or more embodiments, the first die 502 and the second die 504 have any or all of the features and functionalities of the first die 102 and the second die 104 as described in connection with FIGS. 1A and 1B. In one or more embodiments, the side-channel 507 is a microfluidic channel, such as the microfluidic channel 106 discussed in connection with FIGS. 1A and 1B. In one or more embodiments, the side-channel 507 is an air channel. In one or more embodiments, the side-channel width 524 is between 10 to 25 micrometers. In one or more embodiments, the system includes more than one side-channel 507 between the first die 502 and the second die 504. For example, there may be two adjacent channels between the first die 502 and the second die 504.

In the embodiment shown in FIGS. 5A and 5B, the one or more thermal elements 520-2 are placed on an additional thermal layer 518 that is positioned on top of the first die 502. For example, the additional thermal layer 518 may be silicon. FIG. 5B shows a top-down view of the additional thermal layer 518 on top of the first die 502 with one possible formation including one or more thermal elements 520-2 and one or more channels 516-2. In one or more embodiments, the additional thermal layer 518 includes the one or more thermal elements 520-2 at the outer top surface of the additional thermal layer 518, such as pins, fins, pin-fins, or combinations thereof. These one or more thermal elements 520-2 may define one or more channels 516-2 in the outer top surface of the additional thermal layer 518. For example, the one or more channels 516-2 may be microfluidic channels.

In the embodiment shown in FIGS. 5A and 5B, the one or more thermal elements 520-3 are subtractively manufactured directly into the second die 504 without positioning an additional thermal layer 518 on top of the second die 504. These one or more thermal elements 520-3 may be pins, fins, pin-fins, or combinations thereof. In one or more embodiments, the one or more thermal elements 520-3 may define one or more channels 516-3 on the outer surface of the second die 504. For example, the one or more channels 516-3 may be microfluidic channels.

As shown in FIGS. 5A and 5B, an inlet 512-2 is provided to the channel 516-2, and an outlet 514-2 is provided from the channel 516-2. Similarly, an inlet 512-3 is provided to the one or more channels 516-3, and an outlet 514-3 are provided from the one or more channels 516-3.

As shown in FIGS. 5A and 5B, a side-channel 507 may be provided between the first die 502 and the second die 504, wherein the side-channel 507 is not connected with the one or more channels 516-2 and 516-3. In one or more embodiments, an inlet 512-1 and an outlet 514-1 to and/or from the side-channel 507 are provided through a manifold 508-3 that covers the second die 104 and the side-channel 507. In this way, the working fluid is configured to flow on the one or more channels 516-2 of the additional thermal layer 518 and/or does not interfere with the side-channel 507 cooling system, nor with the second die 504 cooling system. Similarly, the working fluid that is configured to flow on the side-channel 507 does not interfere with the second die 504 cooling system. In one or more embodiments, the one or more channels 516-2 and the side-channel 507 are connected with each other. In one or more embodiments, the one or more channels 516-3 and the side-channel 507 are connected with each other.

As shown in FIG. 5A, the additional thermal layer 518 including the one or more thermal elements 520-2 and the one or more channels 516-2 is capped with a manifold 508. For example, the manifold 508-2 may provide a closed volume for any working fluid to travel therein and the manifold 508-3 further provides an inlet 512-2 and an outlets 514-2 to the one or more channels 516-2. A shown in FIGS. 5A and 5B the inlet 512-2 and the outlet 514-2 is provided through the side of the manifold 508-2. In one or more embodiments, the inlet and the outlet may be provided through the top of the manifold 508-2. It should be noted that even if the example here shows one inlet 512-2 and one outlet 514-2, the thermal system may, in one or more embodiments, includes any number of inlets and/or outlets to and/or from the one or more channels 516-2.

As further shown in FIG. 5A, the second die 504, including the one or more thermal elements 520-3 and the side-channel 507, are covered by manifold 508-3. In one or more embodiments, the inlet 512-1 and the outlet 514-1 to the side-channel 507 are provided through the top of the manifold 508-3. In one or more embodiments, the inlet and the outlet are provided through the side of the manifold. It should be noted that even if the example here shows one inlet 512-1 and one outlet 514-1, the thermal system includes, in one or more embodiments, any number of inlets and outlets to and from the side-channel 507. In one or more embodiments, the inlet 512-3 and the outlet 514-3 to the one or more channels 516-3 are provided through the top of the manifold 508-3. In one or more embodiments, the inlet and the outlet are provided through the side of the manifold 508-3. It should be noted that even if the example here shows one inlet 512-3 and one outlet 514-3, the thermal system includes, in one or more embodiments, any number of inlets and outlets to and from the one or more channels 516-3.

In one or more embodiments, the system further includes one or more pumps that delivers the working fluid to the one or more channels 516-2, 516-3 and the side-channel 507. For example, the one or more pumps may provide pressurized working fluid to the one or more channels 516-2, 516-3 through the inlets 512-2, 512-3. Similarly, the one or more pumps may provide pressurized working fluid to the side-channel 507 through the inlet 512-1. In one or more embodiments, the system further includes one or more fans that deliver gaseous working fluid to the one or more channels 516-2, 516-3, the side-channel 507, or a combination thereof.

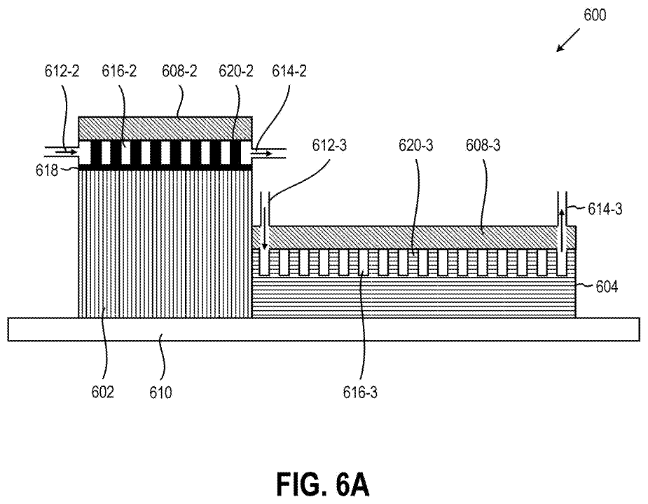

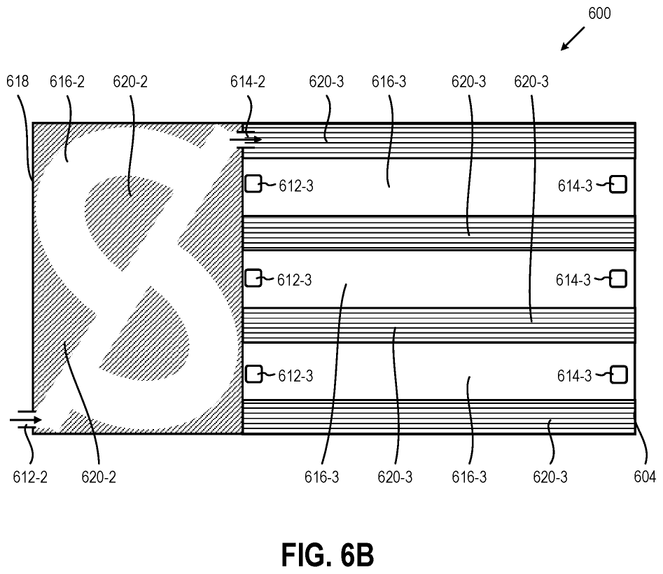

FIGS. 6A and 6B illustrate a thermal management system 600 for an electronic device having two dies (602, 604) laterally adjacent to each other and configured to receive separate working fluids, in accordance with at least one or more embodiments. FIG. 6A shows a cross-sectional sideview of a first die 602 and a second die 604 that are laterally adjacent to each other and configured to receive separate working fluids. FIG. 6B shows a cross-sectional top-down view of one or more thermal elements (620-2 and 620-3) located on top of the first die 602 and the second die 604 respectively.

As shown in FIG. 6A, the thermal management system 600 includes a circuit board 610, a first die 602 and a second die 604, wherein the first die 602 and the second die 604 are laterally adjacent to each other and connected to the circuit board 610. In one or more embodiments, the first die 602 and the second die 604 have any or all of the features and functionalities of the first die 102 and the second die 104 as described in connection with FIGS. 1A and 1B.

The thermal management system 600 further includes a first inlet 612-2 for the first die 602 configured to receive a first working fluid at a first temperature and a second inlet 612-3 for the second die 604 configured to receive a second working fluid at a second temperature. In one or more embodiments, the first temperature and the second temperature are different. For example, the first working fluid may be received at 15 degree Celsius, and the second working fluid may be received at 45 degrees Celsius.

In one or more embodiments, one or more thermal elements (620-2, 620-3) are placed on top of the first die 602 and the second die 604 respectively. In the embodiment shown in FIGS. 6A and 6B, the one or more thermal elements 620-2 are placed on an additional thermal layer 618 that is positioned on top of the first die 602. For example, the additional thermal layer 618 may be silicon material. In one or more embodiments, the additional thermal layer 618 includes the one or more thermal elements 620-2 at the outer top surface of the additional thermal layer 618. The one or more thermal elements 620-2 may be pins, fins, pin-fins, or a combination thereof. These one or more thermal elements 620-2 may define one or more channels 616-2 in the outer top surface of the additional thermal layer 618. For example, the one or more channels 616-2 may be microfluidic channels.

In the embodiment shown in FIGS. 6A and 6B, the one or more thermal elements 620-3 are carved directly to the second die 604 without positioning an additional thermal layer on top of the second die 604. These one or more thermal elements 620-3 may be pins, fins, pin-fins, or combination thereof. In one or more embodiments, the one or more thermal elements 620-3 define one or more channels 616-3 on the outer surface of the second die 604. For example, the one or more channels 616-3 may be microfluidic channels.

As shown in FIG. 6A, the additional thermal layer 618 including the one or more thermal elements 620-2 and the one or more channels 616-2 is capped with a manifold 608-2. For example, the manifold 608-2 may provide a closed volume for any working fluid to travel and wherein the manifold 608-2 further provides an inlet 612-2 and an outlet 614-2 to the one or more channels 616-2. Similarly, the second die 604 including the one or more thermal elements 620-3 and the one or more channels 616-3 is capped with a manifold 608-3. For example, the manifold 608-3 may provide a closed volume for any working fluid to travel and wherein the manifold 608-3 further provides multiple inlets 612-3 and multiple outlets 614-3 to the one or more channels 616-3.

Furthermore, 6B shows a top-down view of the first die 602 and the second die 604 with one possible formation including one or more thermal elements 620-2, 620-3 and one or more channels 616-2, 616-3. As shown in FIGS. 6A and 6B, one or more inlets 612-3 are provided to the one or more channels 616-3, and one or more outlets 614-3 are provided from the one or more channels 616-3.

As shown in FIGS. 6A and 6B, the one or more channels 616-2 and the one or more channels 616-3 are not connected to each other. In this way, the working fluid configured to flow on the one or more channels 616-2 of the additional thermal layer 618 does not interfere with the second die 604 cooling system.

FIG. 7A illustrates a thermal management system 700 for an electronic device having two separate fluid reservoirs, in accordance with at least one or more embodiments. As shown in FIG. 7A, a fluid reservoir 728-1 is connected to an inlet 712-1 and to an outlet 714-1, while fluid reservoir 728-2 is connected to an inlet 712-2 and to an outlet 714-2. Each system may operate one or more of a liquid working fluid, a gaseous working fluid, a single-phased working fluid, and a two-phase working fluid. Each system may further operate working fluids at different temperatures.

In one or more embodiments, one or more of the fluid reservoirs 728-1, 728-2 are used with any inlet (e.g., inlet 112, 212, 312-1, 312-2, 412, 412, 512-1, 512-2, 512-3, 612-2, 612-3) or outlet (e.g., 114, 214, 314-1, 314-2, 414-1, 414-2, 514-1, 514-2, 514-3, 614-2, 614-3) described herein. For example, the inlet 712-1 or the inlet 712-2 may be identical to the inlets 312-1, 312-2 as shown in FIG. 3A.

In one or more embodiments, there are three or more separate fluid reservoirs connected to three or more inlets, such as the inlets 512-1, 512-2, 512-3 in FIG. 5A. In one or more embodiments, the system 700 includes one or more pumps, one or more fans, one or more heat exchanges, or a combination thereof, as further discussed in connection with FIG. 7B.

FIG. 7B illustrates a thermal management system 750 for an electronic device having a single fluid reservoir for two inlets and two or more outlets, in accordance with at least one or more embodiments. As shown in FIG. 7B, a fluid reservoir 728-3 is connected to an inlet 712-3, an inlet 712-4, an outlet 714-3, and an outlet 714-4. The system 750 further includes one or more pumps (or alternatively fans) 732 and one or more heat exchangers 730. The one or more pumps 732 may deliver working fluid to one of the thermal management systems as described in connection to prior figures. For example, the pump 732 may provide pressurized water to the thermal management systems through the one or more inlets. Similarly, a fan may provide pressurized airflow to the thermal management systems through the one or more inlets. A heat exchanger 730 may further cool or heat the working fluid received from the fluid reservoir 728-3 before it is received by the thermal management system (e.g., the thermal management system of 100, 200, 300, 400, 500, 600).

The thermal management system 750 may operate one or more of a liquid working fluid, a gaseous working fluid, a single-phased working fluid, and a two-phase working fluid. In one or more embodiments, the fluid reservoirs 728-3 is used with any inlet (e.g., inlet 112, 212, 312-1, 312-2, 412, 412, 512-1, 512-2, 512-3, 612-2, 612-3) or outlet (e.g., 114, 214, 314-1, 314-2, 414-1, 414-2, 514-1, 514-2, 514-3, 614-2, 614-3) described herein. In one or more embodiments, the inlet 712-3 and the inlet 712-4 is identical to the inlets 612-2, 612-3 shown in FIG. 6A.

In one or more embodiments, there are three or more inlets and/or three or more outlets connected to the fluid reservoir 728-3, such as the inlets 512-1, 512-2, and 512-3 in FIG. 5A.

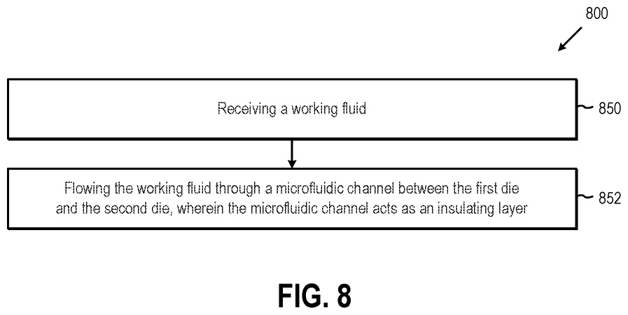

FIG. 8 illustrates a series of acts 800 for preventing heat transfer between a first die and a second die, in accordance with at least one or more embodiments. While FIG. 8 illustrates acts according to one or more embodiments, alternative embodiments may omit, add to, reorder, and/or modify any of the acts shown in FIG. 8. The acts of FIG. 8 can be performed as part of a method. Alternatively, a system can perform the acts of FIG. 8. In still further embodiments, a device can perform the acts of FIG. 8.

As shown in FIG. 8, the series of acts 800 may include an act 850 of receiving, from an inlet, a working fluid. In one or more embodiments, the working fluid may be liquid working fluid, or gaseous working fluid. In one or more embodiments, the working fluid may be cooled down to a required temperature before delivered to the microfluidic channel.

The series of acts 800 may also include an act 852 of flowing the working fluid through a microfluidic channel between the first die and the second die, wherein the microfluidic channel acts as an insulating layer. In one or more embodiments, the microfluidic channel width is 10 to 20 micrometers. In one or more embodiments, the microfluidic channel may be capped with a manifold, wherein the manifold provides a closed volume for the microfluidic channel. In one or more embodiments, the manifold may provide the inlet and an outlet for a working fluid to flow to and from the microfluidic channel.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A thermal management system for electronic device, comprising:
a circuit board;
a first die and a second die in an integrated chip, wherein the first die and the second die are laterally adjacent to each other and connected to the circuit board; and
a microfluidic channel between the first die and the second die, wherein the microfluidic channel acts as an insulating layer.

2. The thermal management system of claim 1, wherein the microfluidic channel is capped with a manifold.

3. The thermal management system of claim 2, wherein the manifold includes inlet and outlet to the microfluidic channel.

4. The thermal management system of claim 1, wherein the microfluidic channel is configured to transport a working fluid.

5. The thermal management system of claim 4, wherein the working fluid is liquid working fluid.

6. The thermal management system of claim 4, wherein the working fluid is gaseous working fluid.

7. The thermal management system of claim 1, wherein the system further includes a pump that delivers a working fluid to the microfluidic channel.

8. The thermal management system of claim 1, wherein the first die is configured to operate below a first junction temperature and the second die is configured to operate under a second junction temperature, and wherein the first junction temperature and the second junction temperature are different.

9. The thermal management system of claim 1, wherein the first die and the second die are one or more of a logical chip, a memory chip, an application-specific chip, and a system-on-a-chip.

10. The thermal management system of claim 1, wherein the microfluidic channel includes thermal elements.

11. The thermal management system of claim 10, wherein the thermal elements are on one or more of the first die and the second die.

12. The thermal management system of claim 10, wherein the thermal elements are on a surface of one or more of the first die and the second die.

13. The thermal management system of claim 10, wherein the thermal elements is one or more of a pin, a fin, and a pin-fin.

14. The thermal management system of claim 10, wherein the thermal elements are formed by removing die material from an outer surface of one or more of the first die and the second die.

15. The thermal management system of claim 14, wherein removing a die material from the outer surface of the first die or the second die is performed by one or more of laser etching and ablation.

16. The thermal management system of claim 10, wherein the thermal elements are formed by additive manufacturing process to a top surface of the first die or the second die.

17. A thermal management system for electronic device, comprising:
a circuit board;
a first die and a second die, wherein the first die and the second die are laterally adjacent to each other and connected to the circuit board;
a side-channel between the first die and the second die, wherein the side-channel acts as an insulating layer; and
one or more thermal elements on top of the first die and the second die.

18. The thermal management system of claim 17, wherein the one or more thermal elements are placed on an additional thermal layer positioned on top of the first die, the second die, and the side-channel.

19. The thermal management system of claim 17, wherein the one or more thermal elements is one or more of a pin, a fin, and a pin-fin.

20. A thermal management system for electronic device, comprising:
a circuit board;
a first die and a second die, wherein the first die and the second die are laterally adjacent to each other and connected to the circuit board;
a first inlet for the first die configured to receive a first working fluid at a first temperature; and
a second inlet for the second die configured to receive a second working fluid at a second temperature, and wherein the first temperature and the second temperature are different.
